(19) United States
(12) Patent Application Publication
(10) Pub. No.: US 2018/0181334 A1
(43) Pub. Date: Jun. 28, 2018

(54) MEMORY CONTROLLER CAPABLE OF PERFORMING SCHEDULED MEMORY MAINTENANCE FROM A SLEEP STATE

(71) Applicant: Intel Corporation, Santa Clara, CA (US)

(72) Inventors: Amir RADJAI, Portland, OR (US); Bezan KAPADIA, Portland, OR (US)

(21) Appl. No.: 15/392,821

(22) Filed: Dec. 28, 2016

(51) Int. Cl. G06F 3/06; G11C 7/22; G11C 5/14

(52) U.S. Cl. CPC G06F 3/0634; G06F 3/0604; G11C 5/148; G11C 7/22; G06F 3/0673

(57) ABSTRACT

A method is described. The method includes periodically maintaining memory devices with circuitry of a memory controller. The circuitry is to act in response to signals from timer and scheduling circuitry that determine when memory maintenance is to occur to which of the memory devices. The periodically maintaining is performed while the memory controller is able to perform read/write operations from/to the memory devices. The method also includes placing the memory controller into a sleep mode in which the memory controller is not able to read/write from/to the memory devices, where, the periodically maintaining continues to be performed while the memory controller is within the sleep mode.

### FIELD OF INVENTION

The field of invention pertains generally to the electronic arts, and, more specifically, to a memory controller capable of performing scheduled memory maintenance from a sleep state.

### BACKGROUND

Computer system designers, particularly with the wide scale emergence of battery powered computing systems (such as smartphones), are particularly motivated to improve the power consumption efficiency of their system. One area of particular focus is the system memory (or main memory) region of the computing system.

### FIGURES

A better understanding of the present invention can be obtained from the following detailed description in conjunction with the following drawings, in which:

FIG. 1 shows a prior art memory subsystem;

FIG. 2 shows an improved memory subsystem;

FIG. 3 shows a method performed by the improved memory subsystem;

FIG. 4 shows a computing system.

### DETAILED DESCRIPTION

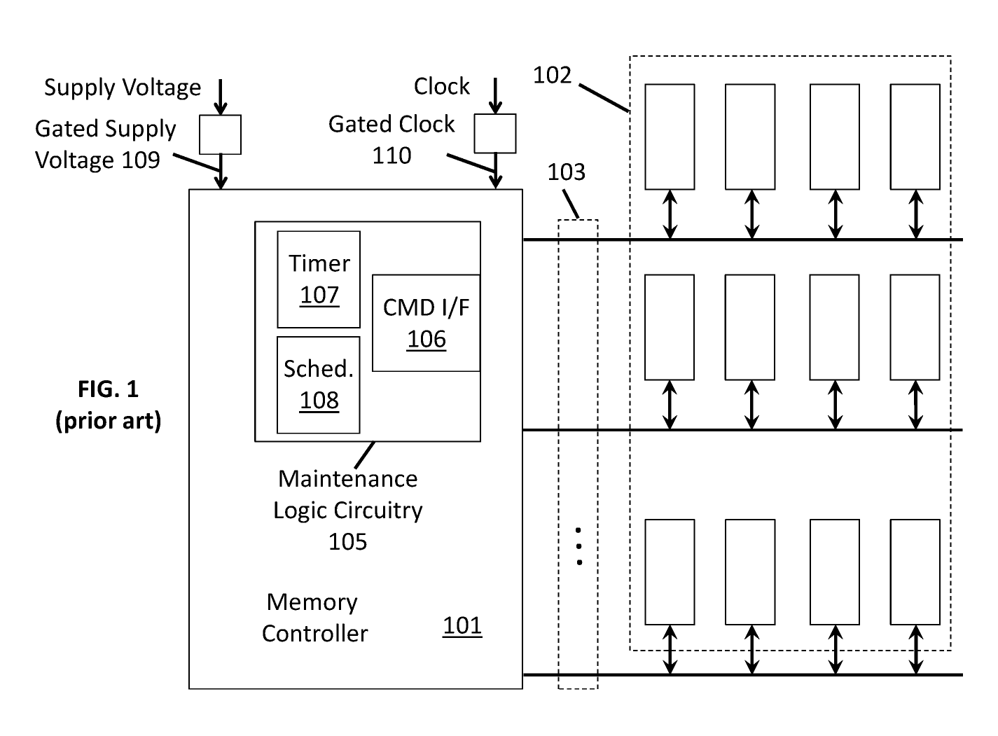

FIG. 1 shows a prior art memory subsystem 100 that includes a memory controller 101 and multiple dual in-line memory modules (DIMMs) 102 plugged into multiple memory channels 103 that emanate from the memory controller 101. In various implementations, multiple memory chips are coupled in parallel to form a rank having a data width that is equal to the number of parallel memory chips times the data width of each parallel memory chip. Depending on implementation, one or more ranks may exist on a same DIMM. The memory channels 103 are typically implemented in accordance with an industry standard or specification such as those promulgated by the Joint Electron Device Engineering Council (JEDEC) that may include, but are not limited to, DDR4 (double data rate (DDR) version 4, initial specification published in September 2012 by JEDEC), LPDDR4 (LOW POWER DOUBLE DATA RATE (LPDDR) version 4, JESD209-4, originally published by JEDEC in August 2014), WIO2 (Wide I/O 2 (WideIO2), JESD229-2, originally published by JEDEC in August 2014), HBM (HIGH BANDWIDTH MEMORY DRAM, JESD235, originally published by JEDEC in October 2013), and/or other technologies based on derivatives or extensions of such specifications.

In some examples, DIMMs 102 may include various types of volatile and/or non-volatile memory. Volatile memory may include, but is not limited to, random-access memory (RAM), Dynamic RAM (DRAM), double data rate synchronous dynamic RAM (DDR SDRAM), static random-access memory (SRAM), thyristor RAM (T-RAM) or zero-capacitor RAM (Z-RAM). Non-volatile memory may include, but is not limited to, non-volatile types of memory such as 3-D cross-point memory that are byte or block addressable. These block addressable or byte addressable non-volatile types of memory for DIMMs 102 may include, but are not limited to, memory that use chalcogenide phase change material (e.g., chalcogenide glass), multi-threshold level NAND flash memory, NOR flash memory, single or multi-level phase change memory (PCM), resistive memory, nanowire memory, ferroelectric transistor random access memory (FeTRAM), magnetoresistive random access memory (MRAM) memory that incorporates memristor technology, or spin transfer torque MRAM (STT-MRAM), or a combination of any of the above, or other non-volatile memory types.

As is known in the art, the memory chips and/or the interfaces to them need to be periodically maintained and/or calibrated. For example, according to one maintenance routine, memory channel output drivers are to be calibrated approximately every 100 ms (more specifically, approximately every 128 ms). In order to implement such periodic maintenance routines the memory controller 101 includes maintenance circuitry 105. In various implementations, the maintenance circuitry 105 is responsible for implementing an output driver impedance calibration for each rank in the system at the appropriate periodicity (e.g, as called out by an industry standard or specification). The maintenance circuitry 105, besides command interface circuitry (“CMD I/F”) 106 that sends calibration commands to the memory devices 102 also includes timer circuitry 107 and scheduling circuitry 108 that together are responsible for keeping track of the scheduling of the maintenance routines for each of the ranks in the memory subsystem (the DIMMs 102 themselves maintain calibration circuitry that actually carries out the calibration routines).

Here, as is known in the art, computing systems are becoming increasingly power consumption sensitive (e.g., in the case of battery powered computers such as smartphones) and, in response, designers are motivated to develop increasingly power efficient systems. One industry standard, referred to as Advanced Configuration and Power Interface (ACPI) standard (e.g., Advanced Configuration and Power Interface (ACPI) specification, version 6.1, published by the Unified Extensible Firmware Interface Forum (UEFI), Jan. 2016), defines a highest power state (P0). The P0 state is the only power state at which the component is operable. A hierarchy of multiple performance states are defined to operate out of the P0 power state where increasing performance state in the hierarchy corresponds to higher performance/utility by the component and correspondingly higher power consumption by the component.

In the reverse direction, ACPI also defines lower power states (P1, P2, etc.) in which the component is non operable and each lower power state corresponds to less power consumption by the component and a longer time delay bringing the component back to the operable P0 state. For example, the P2 state consumes less power than the P1 state and a longer amount of time will be expended waiting for the component to reach the P0 state from the P2 state than from the P1 state. Commonly, one of the low power states (and the even lower power states that are beneath the low power state) is defined to include removal of the power supply voltage and/or removal of one or more clocks that the component operates from.

Accordingly, in the prior art subsystem of FIG. 1, the memory controller 101 includes one or more lower power states in which a supply voltage that supplies the maintenance circuitry (and other parts) of the memory controller 101 is removed and/or one or more clocks that the maintenance circuitry's (and other memory controller parts') operation depends upon are removed. In this state, the memory chips are placed in a self-refresh mode so that they can keep their information even though the memory controller 101, which nominally provides refresh signals to the memory chips, is no longer operable. FIG. 1 depicts the ability to remove one or more memory controller supply voltages as gated supply voltage 109 and depicts the ability to remove one or more memory controller clocks as gated clock 110.

A problem can arise if the memory controller 101 is expected to drop down into one or more low power states in which the supply voltage and/or clock(s) provided to the maintenance circuitry 105 is removed. Specifically, when the power/clock(s) are removed from the maintenance circuitry 105, the maintenance circuitry 105 loses the state of its scheduling for the maintenance of the memory ranks.

For example, consider a scenario in which the memory controller 101 is woken up (transitioned from a deeper low power state to the P0 state) in order to respond to a new memory request that was sent to the memory controller 101 by another component in the system (e.g., general purpose processing core, graphics processing unit, network interface unit, etc.). Here, as part of the wake-up transition, the removed power supply and/or clocks are returned to the memory controller 101 and the maintenance circuitry 105. The maintenance circuitry 105, however, having lost its state information from its loss of power/clock, has no choice but to assume a worst case condition in which the rank that is targeted by the new memory request has not actually been maintained within the last 100 ms.

Thus, before a read or write command can be sent by the memory controller 101 to the rank to service the new request, the maintenance circuitry 105 starts its maintenance routine for the rank at a wider initial calibration range (again, because the rank is assumed to not have been calibrated within the last 100 ms) which causes the maintenance routine to consume even more time (e.g. 2 μs or more) than if it had started with a narrower initial calibration range which is typical when the rank is being maintained on schedule. Thus, the memory controller 101 has to impose at least a 2 μs delay before it can begin servicing the request that caused the memory controller 101 to be woken up.

For many use cases, wake up delays (also referred to as a low power state exit) of multiple microseconds for the memory subsystem 100 is not acceptable. For example, in the case of video streaming or real time networking communications. To compensate for this problem, the power management intelligence of the system is designed to prevent the memory controller 101 from entering a low power state which, in turn, prevents the system from reaching a power efficiency that it might have otherwise been able to achieve.

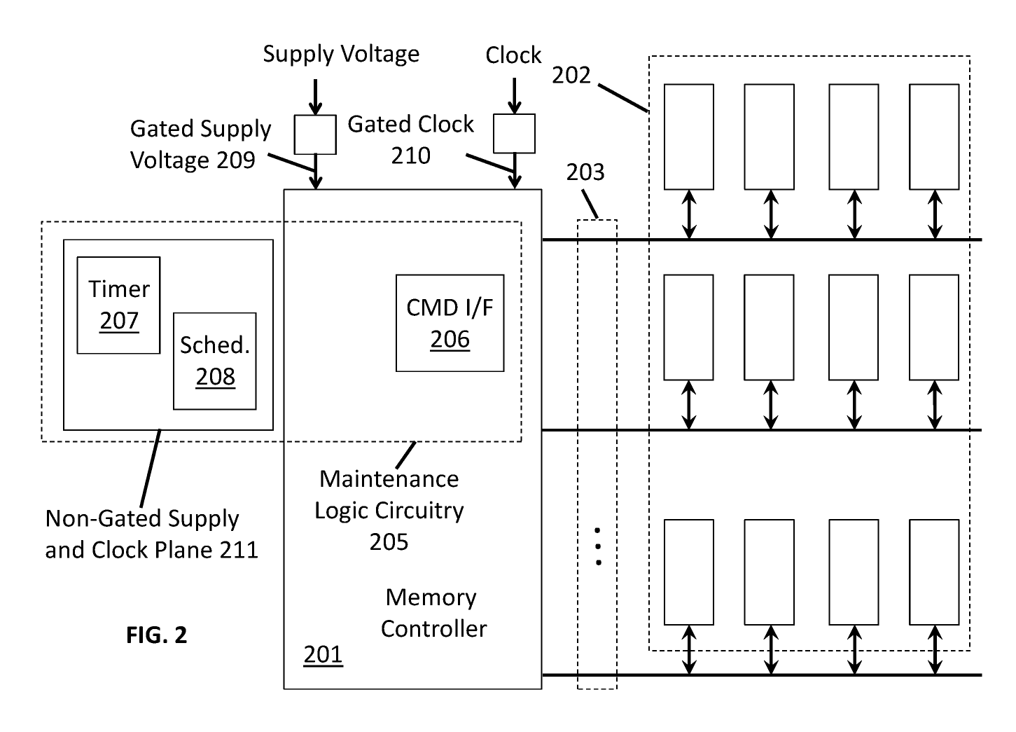

A solution, as observed in FIG. 2, is to move at least the timer 207 and scheduling 208 components of the maintenance circuitry 205 to a non-gated supply and clock plane 211 that is permanent in the sense that power supply voltage is not lowered by the computer system and its clocks are not removed even when power supply and/or clocks are removed from other parts of the memory controller 201. With the timer 207 and scheduling 208 components not losing their state information, they will be able to keep track of when and which ranks are scheduled for maintenance even if the memory controller 201 is presently in a low power state in which it receives no supply voltage and/or its clocks are removed.

In a further embodiment, the timer 207 and scheduling 208 circuitry is powered from a power supply that will receive power so long as the computing system is powered on. In even further embodiments, in order to keep the power consumption of the timer 207 and scheduling 208 circuitry low, the timer 207 and scheduling 208 circuits are clocked with a low speed clock (e.g., in the range of tens of kilo-hertz).

According to the operation of one embodiment of the system of FIG. 2, the timer 207 and the scheduling 208 circuitry maintain the scheduling state of the different memory ranks irrespective of what power state the memory controller 201 is in. Thus, the system may place the memory controller 201 in a low power state in which the memory controller's supply voltage and/or clocks are removed. The timer 207 and scheduling 208 circuitry, however, being supplied from a different power supply rail than the memory controller 201 and still receiving a respective clock, continue to perform their operations. From this state, the system continues to recognize when a next rank is supposed to be maintained even though the memory controller 201 is within an inoperable sleep state.

According to one approach, upon the timer 207 and scheduling 208 circuitry determining that the time has arisen to perform scheduled maintenance on a memory rank, the timer 207 and scheduling 208 circuitry send a signal that causes at least the command interface (“CMD_I/F”) circuitry 206 through which maintenance commands are sent to the rank's memory devices (e.g., a DDR physical layer interface for the rank) to be woken up and made operable so that the maintenance command(s) can be sent to the rank's memory devices and the maintenance routine can be performed on schedule. In an embodiment, this entails waking the memory controller 201 up to a P0 power state but a fairly low performance state in which, e.g., substantially only the command interface circuitry 206 is operable. Here, it is pertinent to point out that in various embodiments when the memory controller 201 is put to sleep the memory devices of the DIMMs 202 are put in a self refresh state (the memory controller typically supplies refresh signals but, e.g., does not provide them when put to sleep).

In various embodiments other components of the memory controller 201 may be woken up along with the command interface circuitry 206 (e.g., circuitry to bring the rank's memory chips out of a self refresh state). The wake up of the command interface circuitry 206 and other parts of the memory controller 201 (if any) includes raising the power supply voltage and/or turning on the clocks of the command interface circuitry 206 and other parts (if any) so that they become operable. Upon the command interface circuitry 206 being woken up, the scheduled maintenance routine for the next rank to be maintained can be performed.

In an embodiment, some form of communication takes place from the timer 207 and/or scheduling 208 circuitry to the command interface circuitry 206 that informs the command interface circuitry 206 not only that the time has arrived for a next calibration but also which rank is to be maintained next (e.g., so that only the specific interface that interfaces to the rank to be maintained is woken up). According to one direct approach, the signaling is direct in that both the wake up signal and the identity of the rank to be calibrated are communicated through hardware wiring from the timer 207 and scheduling 208 circuitry to the memory controller 201 and/or command interface circuitry 206.

In another approach, the communication is indirect. For example, the timer 207 and scheduling 208 circuitry issue, e.g., an interrupt or other event signal to power control software and/or hardware. The power control software and/or hardware, in response, wakes up the memory controller 201 and/or command interface circuitry 206 to initiate the next maintenance routine.

In other embodiments some combination of direct and indirect communication may exist between the timer and scheduling 207, 208 circuitry and the command interface circuitry 206. For example, the timer and scheduling 207, 208 circuitry may cause the memory controller 201 and/or command interface circuitry 206 to be woken up through indirect communication, but, the timer 207 and scheduling 208 circuitry inform the command interface circuitry 206 of the identity of the next rank to be maintained through direct communication (e.g., upon wake up, the command interface circuitry 206 is designed to poll a register in the scheduling 208 circuitry that identifies which rank is to be maintained next).

In still other embodiments, in order to perform scheduled maintenance without having to wake up the entire memory controller 201 (e.g., in order to simply maintain a rank without any new memory access requests being directed to the memory controller 201), the memory controller 201 is woken up to a lower performance state that limits the performance of the memory controller 201 primarily to performing maintenance on a memory rank. Here, for instance, as described above, from the highest (P0) power state, multiple performance states may be configured for a system component in which each higher performance state corresponds to more performance by the component and more power consumption by the component.

By configuring, e.g., a fairly low memory controller performance state in which primarily only the maintenance circuitry of the memory controller 201 is operable (e.g., one or more circuits needed to fully service read and/or write requests are not operable), the memory controller 201 may be placed in this lower performance state so that it can perform the maintenance operation but will consume little power beyond the power needed to perform the maintenance operation. The lower performance state may be realized, e.g., by power gating the command interface circuitry 206 differently than other components within the memory controller 201 such that the command interface circuitry 206 receives a supply voltage and clock(s) but other components of the memory controller 201 do not receive the supply voltage and/or clock(s). Again, such a lower performance state is utilized when a memory rank needs to be maintained when there are no new memory access requests pending for the memory controller 201, so the memory controller as a whole can remain in a sleep state.

With the memory ranks being maintained on schedule even if the memory controller 201 remains in a low power, inoperable state, the overall system is able to respond much more efficiently to sudden changes in internal traffic flow. That is, the system is better able to take advantage of memory quiet times to conserver power yet suitably respond to memory access request events that cause the memory controller 201 as a whole to be woken up (such as one or more other components in the system direct a read/write request to the memory controller to access the memory 202 which may the system memory, also referred to as main memory, of a computing system).

However, unlike the prior art approach in which the memory controller 201 must wait until 2 μs or more are consumed before it can service the read/write request that woke it up because it is waiting to calibrate the targeted rank according to a worst case assumption, instead, upon wake up, the memory ranks are known to have been properly maintained. As such, the memory controller wakes up without any maintenance dependency on its memory ranks and can service the request from the requesting component substantially immediately (e.g., after the memory controller's own wake up latency).

In this manner, the memory controller 201 can be rapidly put into a sleep mode, woken up to service a sudden memory access request and then be placed back to sleep again. In the prior art approach this was not feasible because the time spent waiting for one or more of the memory ranks to be maintained drastically affected the power management control's freedom to place the memory controller into a sleep state. As such, the memory controller remained operable and consumed substantial power even thought it might not be used for extended periods of time.

As mentioned above, in order to keep the power consumption of the timer 207 and scheduling 208 circuitry low, the timer 207 and scheduling 208 circuitry are designed to receive a low speed clock (e.g., less than 100 kilohertz such as in the tens of kilohertz). In order to successfully schedule all the ranks in the system with such a low clock speed, the maintenance routines are interleaved in time across the various ranks rather than calibrating the ranks simultaneously or immediately sequentially (one immediately after the other).

For example, in one embodiment, the clock that is sent to the timer circuitry 207 at least has a frequency of approximately 30 kHz. A 30 kHz clock corresponds to one clock tick every 33 μs. If there are 4 ranks in the system, maintenance on any rank consumes no more than 1 μs, and each rank is to be maintained every 100 ms, then, it is straightforward to schedule maintenance routines for each of the ranks. For, instance, consecutive maintenance routines across different ranks could be scheduled 25 ms apart. That is, calibrating four different ranks in sequence every 25 ms consumes 100 ms. Repeating the process sets the periodicity of maintenance for any particular rank every 100 ms (which again, e.g., is the industry standard requirement). With a 33 μs master clock, one maintenance routine every 25 ms is easily scheduled as approximately one routine every 757 clock cycles. Note that the scheduling circuitry 208 would not be able to schedule routines 2 or 3 μs apart because the temporal granularity of the timer is approximately ten times coarser than that (33 μs). Hence, to repeat the point, spreading the scheduled maintenance routines out over time permits the lower speed clock to properly schedule the routines.

Thus the timer circuitry 207 may be designed to include a counter that toggles (counts a full loop and then increments to zero) every 757 clock cycles. More specifically, in an embodiment, the timer circuitry 207 is implemented with a first counter that receives the low speed clock and increments its count value with each clock tick. The scheduling circuitry 208 is coupled to receive the count value from the first counter and maintains a second counter whose value identifies the next rank to be maintained.

Each time the first counter value reaches, e.g., a value of 757, the scheduling circuitry 208 increments the second counter value to identify the next rank to be maintained, sends a signal to wake up the command interface circuitry 206 and resets the first counter within the timer circuitry 207. The second counter can be designed to rollover to its initial value after its count reaches a value equal to (or otherwise representative of) all the ranks in the DIMMs 202. In various embodiments the timer and scheduling circuits 207, 208 may have associated configuration register space to establish their roll-over values to effect correct maintenance timings for different numbers of ranks and/or different low speed clock frequencies.

Although the above discussion has been directed to driver impedance calibration, other forms of periodic maintenance may be carried out by the DIMMs 202. That is, command interface circuitry 206 may be seen more broadly as capable of sending commands for various forms of maintenance besides output driver impedance calibration.

Some examples of other types of maintenance that may be performed periodically include: 1) temperature sensing (here, temperature sensors that are physically integrated with the memory devices on the DIMMs are periodically read and signal timings for the memory devices may be adjusted based on these readings); 2) delay-locked loop (DLL) and/or phase locked loop (PLL) circuit adjustments (e.g., the delay (or other signal or timing characteristic) of a DLL or PLL that is used to establish one or more clocks utilized by the memory devices is periodically monitored and/or adjusted); 3) calibration of the timing of the data strobes (DQS), also referred to as DQS training. In still other embodiments, conceivably, maintenance circuitry may also be present on the memory controller (and woken up akin to the command interface circuitry 206 when it is to be used to perform a specific maintenance task) in lieu of maintenance circuitry that resides in the DIMMs 202 and/or in combination with maintenance circuitry that resides in the DIMMs 202.

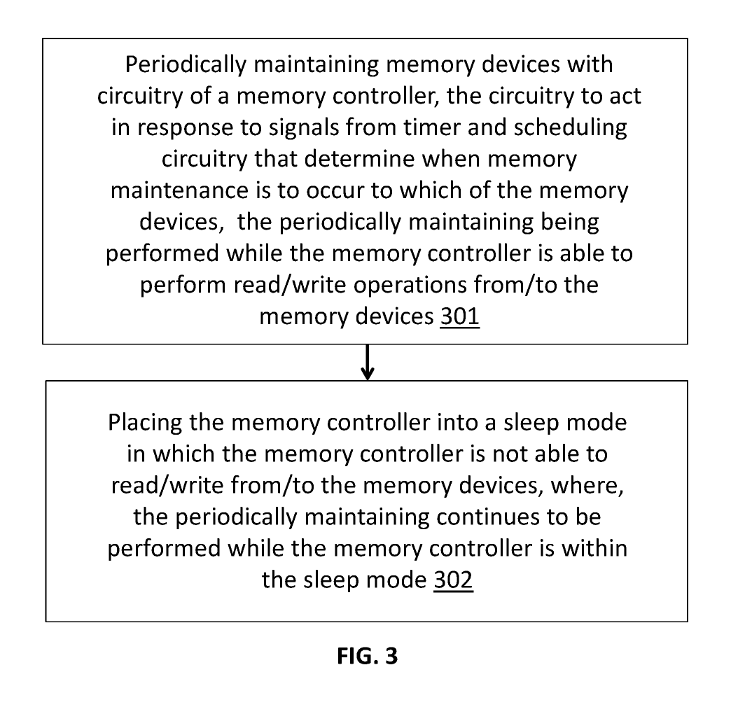

FIG. 3 shows a method. The method includes periodically maintaining 301 memory devices with circuitry of a memory controller. The circuitry is to act in response to signals from timer and scheduling circuitry that determine when memory maintenance is to occur to which of the memory devices. The periodically maintaining is performed while a memory controller is able to perform read/write operations from/to said memory devices. The method also includes placing 302 the memory controller into a sleep mode in which the memory controller is not able to read/write from/to the memory devices, where, the periodically maintaining continues to be performed while the memory controller is within the sleep mode.

Note that the timer circuitry 207, scheduling circuitry 208 and command interface circuitry 206 may be implemented in one or more different types of circuitry such as hardwired dedicated logic circuitry, programmed logic circuitry (e.g., field programmable gate array (FPGA), programmable logic array (PLA), programmable logic device (PLD), etc.) or circuitry that executes some form of program code (e.g., an embedded processor or microcontroller that executes program code). Further still, at least the command interface circuitry 206 may also include various forms of analog or mixed signal (analog and digital) circuitry.

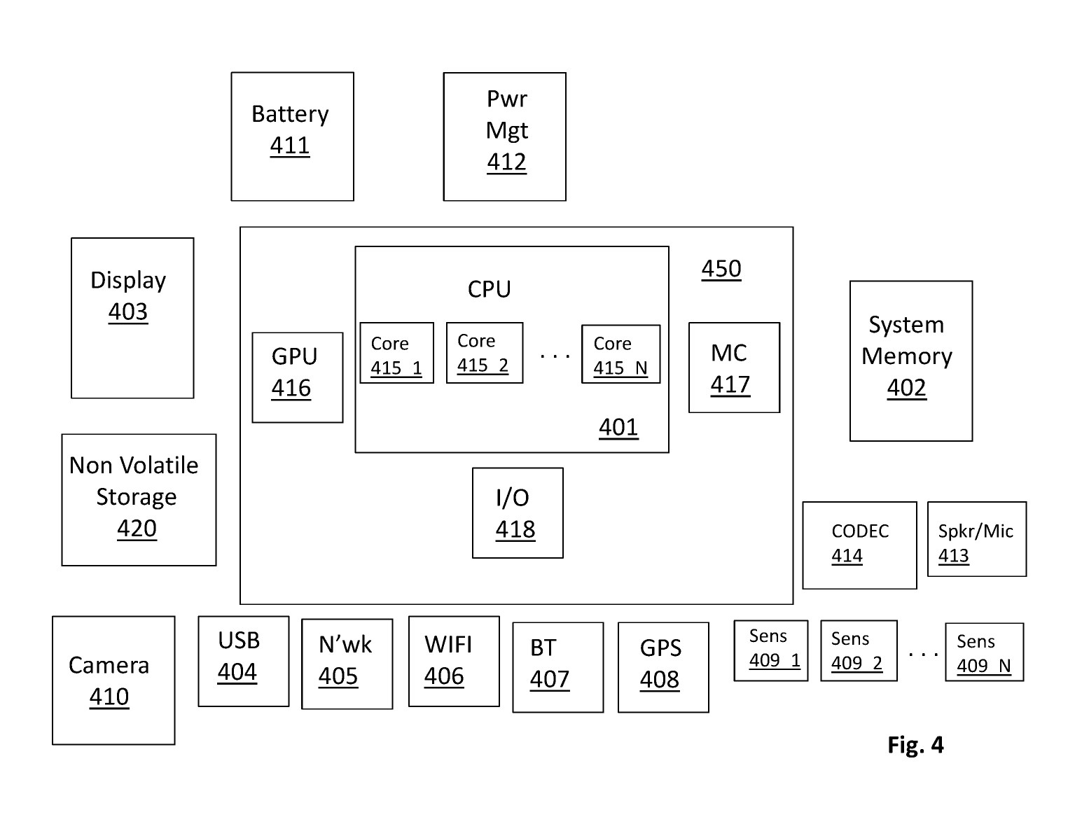

FIG. 4 shows a depiction of an exemplary computing system 400 such as a personal computing system (e.g., desktop or laptop) or a mobile or handheld computing system such as a tablet device or smartphone, or, a larger computing system such as a server computing system. As observed in FIG. 4, the basic computing system may include a central processing unit 401 (which may include, e.g., a plurality of general purpose processing cores and a main memory controller disposed on an applications processor or multi-core processor), system memory 402, a display 403 (e.g., touchscreen, flat-panel), a local wired point-to-point link (e.g., USB) interface 404, various network I/O functions 405 (such as an Ethernet interface and/or cellular modem subsystem), a wireless local area network (e.g., WiFi) interface 406, a wireless point-to-point link (e.g., Bluetooth) interface 407 and a Global Positioning System interface 408, various sensors 409_1 through 409_N (e.g., one or more of a gyroscope, an accelerometer, a magnetometer, a temperature sensor, a pressure sensor, a humidity sensor, etc.), a camera 410, a battery 411, a power management control unit 412, a speaker and microphone 413 and an audio coder/decoder 414.

An applications processor or multi-core processor 450 may include one or more general purpose processing cores 415 within its CPU 401, one or more graphical processing units 416, a memory management function 417 (e.g., a memory controller) and an I/O control function 418. The general purpose processing cores 415 typically execute the operating system and application software of the computing system. The graphics processing units 416 typically execute graphics intensive functions to, e.g., generate graphics information that is presented on the display 403. The memory control function 417 interfaces with the system memory 402. The system memory 402 may be a multi-level system memory.

The memory controller, as described at length above, may be put into a sleep state while timer and scheduling circuitry used to maintain memory maintenance timings remains powered on and operable so that periodic maintenance on the memory devices can continue to be performed on schedule even though the memory controller is asleep.

Each of the touchscreen display 403, the communication interfaces 404-407, the GPS interface 408, the sensors 409, the camera 410, and the speaker/microphone codec 413, 414 all can be viewed as various forms of I/O (input and/or output) relative to the overall computing system including, where appropriate, an integrated peripheral device as well (e.g., the camera 410). Depending on implementation, various ones of these I/O components may be integrated on the applications processor/multi-core processor 450 or may be located off the die or outside the package of the applications processor/multi-core processor 450. The mass storage of the computing system may be implemented with non volatile storage 420 which may be coupled to the I/O controller 418 (which may also be referred to as a peripheral control hub).

Embodiments of the invention may include various processes as set forth above. The processes may be embodied in machine-executable instructions. The instructions can be used to cause a general-purpose or special-purpose processor to perform certain processes. Alternatively, these processes may be performed by specific hardware components that contain hardwired logic for performing the processes, or by any combination of software or instruction programmed computer components or custom hardware components, such as application specific integrated circuits (ASIC), programmable logic devices (PLD), digital signal processors (DSP), or field programmable gate array (FPGA).

Elements of the present invention may also be provided as a machine-readable medium for storing the machine-executable instructions. The machine-readable medium may include, but is not limited to, floppy diskettes, optical disks, CD-ROMs, and magneto-optical disks, FLASH memory, ROMs, RAMs, EPROMs, EEPROMs, magnetic or optical cards, propagation media or other type of media/machine-readable medium suitable for storing electronic instructions. For example, the present invention may be downloaded as a computer program which may be transferred from a remote computer (e.g., a server) to a requesting computer (e.g., a client) by way of data signals embodied in a carrier wave or other propagation medium via a communication link (e.g., a modem or network connection).

Embodiments of an apparatus have been described above where the apparatus includes a memory controller comprising timer and scheduling circuitry that determine when periodic maintenance is to be performed on a memory device. The memory controller is coupled to receive a gated power supply voltage and/or a gated clock signal. The gated power supply and/or the gated clock signal are to be removed in order to place the memory controller into a low power state in which the memory controller is not able to read/write from/to the memory device. The timer and scheduling circuitry are not coupled to operate from the gated power supply voltage and/or the gated clock signal so that the timer and scheduling circuitry remain operable while the memory controller is within the low power state.

The maintenance may be to calibrate a driver impedance. The maintenance may be to monitor a temperature of the one or more memory devices. The maintenance may be to adjust timings of a delayed-lock loop circuit and/or a phase locked loop circuit. The timer and scheduling circuitry may receive a clock having a frequency less than 100 khZ. The timer and scheduling circuitry can include a counter whose value determines when a next scheduled maintenance operation is to begin. The timer and scheduling circuitry may include a counter whose value determines which rank is to next be maintained.

A computing system having the apparatus described just above has also been described.

Embodiments of a method have been described above where the method includes periodically maintaining memory devices with circuitry of a memory controller. The circuitry is to act in response to signals from timer and scheduling circuitry that determine when memory maintenance is to occur to which of the memory devices. The periodically maintaining is performed while the memory controller is able to perform read/write operations from/to the memory devices. The method also includes placing the memory controller into a sleep mode in which the memory controller is not able to read/write from/to the memory devices. The periodically maintaining continues to be performed while the memory controller is within said sleep mode.

The method may further include, upon the timer and scheduling circuitry determining, while the memory controller is within the sleep state, that a next one or more of the memory devices are to be maintained, waking up circuitry of the memory controller to send a maintenance command to the one more of the memory devices. The method may further comprise waking the memory controller up to service a read/write request directed to said memory devices, wherein, the memory devices are properly maintained as of said waking up of the memory controller so that servicing the read/write request is not delayed on account of an assumption that the memory devices have not been properly maintained.

The maintaining of the memory devices may include calibrating a driver impedance. The maintaining may include monitoring a temperature of the memory devices. The maintaining may include adjusting timings of a delayed-lock loop circuit and/or a phase locked loop circuit.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

1. An apparatus, comprising:
a memory controller comprising timer and scheduling circuitry that determine when periodic maintenance is to be performed on a memory device, said memory controller coupled to receive a gated power supply voltage and/or a gated clock signal, said gated power supply and/or said gated clock signal to be removed in order to place said memory controller into a low power state in which said memory controller is not able to read/write from/to said memory device, said timer and scheduling circuitry not coupled to operate from said gated power supply voltage and/or said gated clock signal so that said timer and scheduling circuitry remain operable while said memory controller is within said low power state.

2. The apparatus of claim 1 wherein said maintenance is to calibrate a driver impedance.

3. The apparatus of claim 1 wherein said maintenance is to monitor a temperature of the one or more memory devices.

4. The apparatus of claim 1 wherein said maintenance is to adjust timings of a delayed-lock loop circuit and/or a phase locked loop circuit.

5. The apparatus of claim 1 wherein said timer and scheduling circuitry is to receive a clock having a frequency less than 100 khZ.

6. The apparatus of claim 1 wherein said timer and scheduling circuitry comprises a counter whose value determines when a next scheduled maintenance operation is to begin.

7. The apparatus of claim 1 wherein said timer and scheduling circuitry comprises a counter whose value determines which rank is to next be maintained.

8. A computing system, comprising:
one or more processing cores;
a system memory;
a display;
a memory controller coupled to the system memory, a memory controller comprising timer and scheduling circuitry that determine when periodic maintenance is to be performed on the system memory, said memory controller coupled to receive a gated power supply voltage and/or a gated clock signal, said gated power supply and/or said gated clock signal to be removed in order to place said memory controller into a low power state in which said memory controller is not able to read/write from/to said system memory, said timer and scheduling circuitry not coupled to operate from said gated power supply voltage and/or said gated clock signal so that said timer and scheduling circuitry remain operable while said memory controller is within said low power state.

9. The apparatus of claim 8 wherein said maintenance is to calibrate a driver impedance.

10. The apparatus of claim 8 wherein said maintenance is to monitor a temperature of the one or more memory devices.

11. The apparatus of claim 8 wherein said maintenance is to adjust timings of a delayed-lock loop circuit and/or a phase locked loop circuit.

12. The apparatus of claim 8 wherein said timer and scheduling circuitry is to receive a clock having a frequency less than 100 khZ.

13. The apparatus of claim 8 wherein said timer and scheduling circuitry comprises a counter whose value determines when a next scheduled maintenance operation is to begin.

14. The apparatus of claim 8 wherein said timer and scheduling circuitry comprises a counter whose value determines which rank is to next be maintained.

15. A method, comprising:
periodically maintaining memory devices with circuitry of a memory controller, said circuitry to act in response to signals from timer and scheduling circuitry that determine when memory maintenance is to occur to which of the memory devices, said periodically maintaining being performed while the memory controller is able to perform read/write operations from/to said memory devices;
placing said memory controller into a sleep mode in which said memory controller is not able to read/write from/to said memory devices, said periodically maintaining continuing to be performed while said memory controller is within said sleep mode.

16. The method of claim 15 further comprising upon said timer and scheduling circuitry determining, while said memory controller is within said sleep state, that a next one or more of the memory devices are to be maintained, waking up circuitry of said memory controller to send a maintenance command to said one more of the memory devices.

17. The method of claim 15 further comprising waking said memory controller up to service a read/write request directed to said memory devices, wherein, said memory devices are properly maintained as of said waking up of said memory controller so that servicing said read/write request is not delayed on account of an assumption that said memory devices have not been properly maintained.

18. The method of claim 15 wherein said maintaining said memory devices comprises calibrating a driver impedance.

19. The method of claim 15 wherein said maintaining comprising monitoring a temperature of said memory devices.

20. The method of claim 15 wherein said maintaining comprises adjusting timings of a delayed-lock loop circuit and/or a phase locked loop circuit.
